(19) United States
(12) Patent Application Publication
(10) Pub. No.: US 2012/0142157 A1
(43) Pub. Date: Jun. 7, 2012

(54) Method of fabricating a semiconductor structure

(76) Inventors: Cheng-Guo Chen, Changhua County (TW); Zhi-Cheng Lee, Tainan City (TW); Shao-Hua Hsu, Taoyuan County (TW); Jung-Tsung Tseng, Tainan City (TW); Chien-Ting Lin, Hsinchu City (TW); Cheng-Hsien Chou, Tainan City (TW)

(21) Appl. No.: 12/961,518

(22) Filed: Dec. 7, 2010

(51) Int. Cl. H01L 21/336; H01L 21/302

(52) U.S. Cl. 438/299; 438/692; 257/E21.409; 257/E21.214

(57) ABSTRACT

The method of fabricating a semiconductor structure according to the present invention includes planarizing an inter-layer dielectric layer and further a hard mask to remove a portion of hard mask in a thickness direction. The remaining hard mask has a thickness less than the original thickness of the hard mask. The remaining hard mask and the dummy gate are removed to form a recess. After a gate material is filled into the recess, a gate with a relatively accurate height can be obtained.

### BACKGROUND OF THE INVENTION

1. Field of the Invention

The present invention relates to a method of fabricating a semiconductor structure, and particularly a method of fabricating a semiconductor structure in which dummy gate rounding phenomena can be avoided during planarization.

2. Description of the Prior Art

With a trend towards scaling town the MOS size, metal gates and high-K (high dielectric constant) materials have been used to replace the conventional polysilicon gate and silicon oxide gate dielectric layer, to reduce leakage current or boron penetration from the polysilicon gate caused by thin thickness of the gate dielectric layer. Leakage current or boron penetration may deteriorate the device performance and the like.

During fabrication of a metal gate, as shown in FIG. 1, a polishing process is often employed to polish an inter-layer dielectric (ILD) layer 2 to expose polysilicon dummy gates 4a and 4b for etch and removal, and after the polysilicon dummy gates 4a and 4b are removed, metal is filled in. However, when there are a plurality of gates with variously large and small sizes on a wafer, rounding phenomena tends to occur to the large dummy gate (such as 4a) due to dishing effect during the polishing, as shown in FIG. 1. Accordingly, the dummy gate 4a resulted after the polishing will have a central height h₁ and an edge height h₂ which are different. This will lead to an inaccurate gate height with respect to large size gates.

Therefore, there is still a need for a novel method of fabricating a semiconductor structure to prevent the device height from being affected by the rounding phenomena which occurs in the fabrication process.

### SUMMARY OF THE INVENTION

An objective of the present invention is to provide a method of fabricating a semiconductor structure to solve the aforesaid rounding issue.

According to one embodiment of the present invention, the method of fabricating a semiconductor structure includes steps as follows. First, a semiconductor substrate is provided. A dummy gate structure is formed on the semiconductor substrate. The dummy gate structure includes an inter layer, a dummy gate, and a hard mask in order from bottom to top. Thereafter, an ILD layer is formed on the semiconductor substrate. The ILD layer is higher than the hard mask. The ILD layer is planarized to further remove a partial thickness of the hard mask. The remaining hard mask has a thickness less than an original thickness of the hard mask. The remaining hard mask is removed through an etch process. The dummy gate is removed.

According to another embodiment of the present invention, the method of fabricating a semiconductor structure includes steps as follows. First, a substrate is provided. A material layer is formed on the substrate. A hard mask is formed on the material layer. The hard mask is patterned. The material layer is etched through the hard mask to form a patterned material layer. A dielectric layer is formed on the substrate. The dielectric layer is higher than the hard mask. The dielectric layer is planarized so as to remove a partial thickness of the hard mask. A remaining hard mask has a thickness less than an original thickness of the hard mask. The remaining hard mask is removed through an etch process. The patterned material layer is removed.

Since in the planarization process in the present invention, the hard mask is only partially removed in the thickness direction, it does not lead the dummy gate to rounding. Accordingly, the depth of the recess obtained by removing all of the material of the dummy gate can be substantially the same as the height of the original dummy gate. Thus the height of the resultant gate after gate material, such as metal, is filled into the recess can be substantially maintained as the desired or designed one.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view illustrating a conventional method of fabricating a semiconductor structure;

FIGS. 2 to 6 are schematic cross-sectional views illustrating an embodiment of the method of fabricating a semiconductor structure according to the present invention; and

FIG. 7 is a schematic cross-sectional view illustrating another embodiment of the method of fabricating a semiconductor structure according to the present invention.

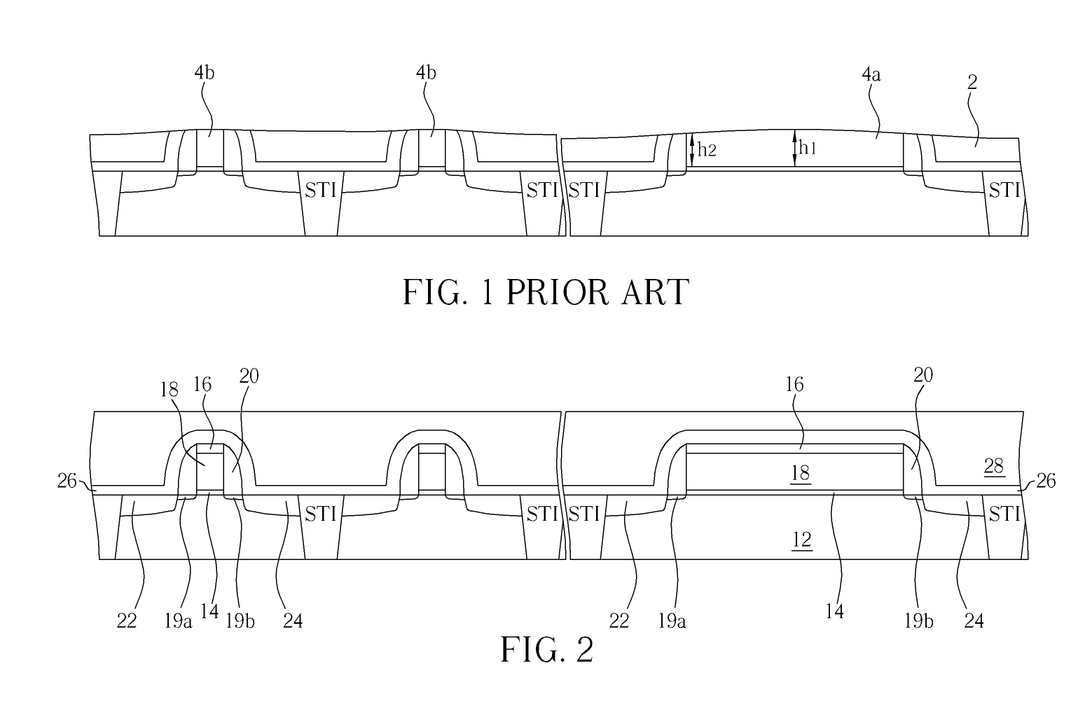

### DETAILED DESCRIPTION

FIGS. 2 to 6 illustrate an embodiment of the method of fabricating a semiconductor structure according to the present invention. As shown in FIG. 2, a semiconductor substrate 12, such as a silicon substrate, a silicon-containing substrate, or a silicon-on-insulator (SOI) substrate, is provided. A dummy gate structure is formed. For example, an inter layer 14, such as barrier layer, work function tuning metal layer, gate dielectric layer or the combination thereof. Material for the gate dielectric layer may include for example oxide or high-K dielectric material. A dummy gate material layer, such as a polysilicon layer, is formed on the inter layer 14. A hard mask 16 is formed on the dummy gate material layer. Material for the hard mask may include for example silicon nitride. The hard mask 16 is patterned through for example a photolithography and an etch processes. The dummy gate material layer is etched through the hard mask 16, to form a dummy gate 18. Lightly-doped source/drain regions 19a and 19b may be further formed in the semiconductor substrate 12 at two sides of the dummy gate 18, respectively.

Thereafter, a spacer 20 may be formed on the sidewall of the dummy gate structure. The spacer may have a single layer or multilayer structure or may include a liner, or be a composition thereof. Material for the space may include for example oxide or nitride. Source/drain regions 22 and 24 are formed in the semiconductor substrate 12 at two sides of the spacer 20, respectively, through incorporation of suitable dopants using the spacer 20 and the hard mask 16 as a mask. Thereafter, a self-alignment metal silicide (salicide) process may be optionally carried out to form a metal silicide layer (not shown) on the surface of the source/drain regions 22 and 24, but not on the dummy gate 18 covered with the hard mask 16. It may be optional to form a contact etch stop layer (CESL) 26 on the semiconductor substrate 12, the spacer 20, and the hard mask 16 or on the metal silicide layer. The CESL 26 can serve as a selective strain scheme (SSS) by applying a stress generated by treatment with heat or W. The material for the CESL may include for example silicon nitride.

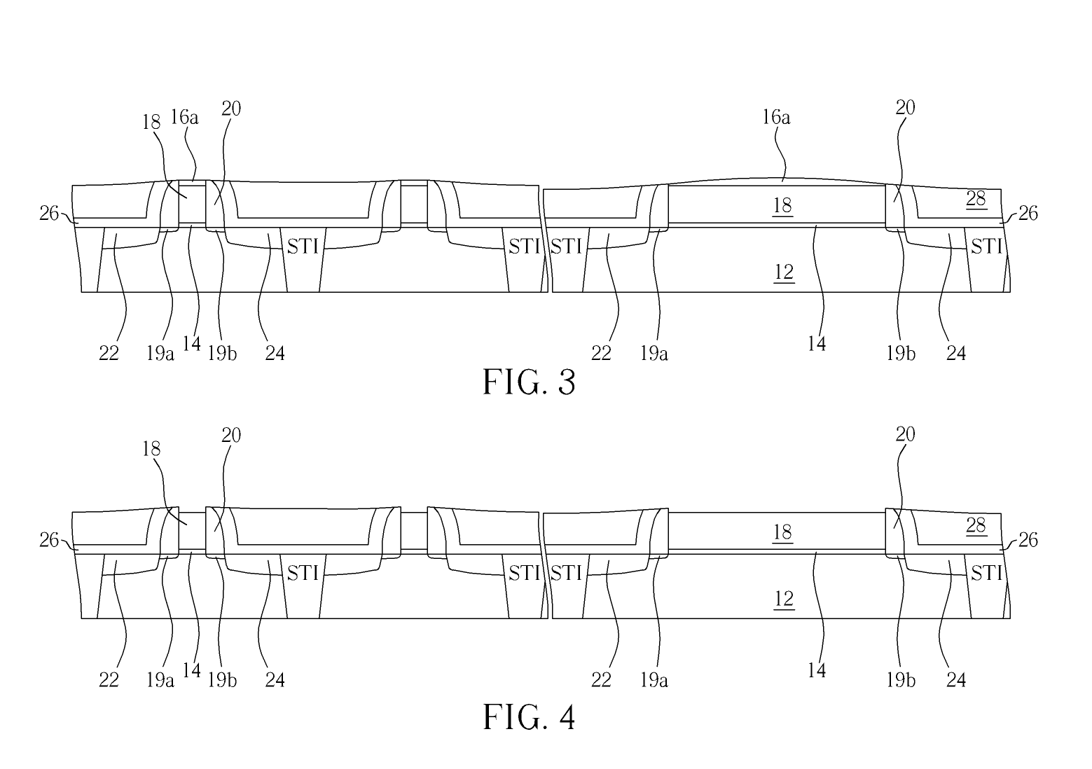

Thereafter, an ILD layer 28 may be formed on the semiconductor substrate 12. Material for the ILD layer 28 may include for example oxide. The thickness of the ILD layer may be sufficient for allowing the ILD layer to be higher than the hard mask 16 and the CESL 26 if formed, for example about thousands angstroms, such as about 2400 angstroms, but not limited thereto. Thereafter, a planarization process is performed on the ILD layer 28. The planarization process may be for example a chemical mechanical polishing (CMP) process. Conditions for one-stage polishing may be used to remove a partial thickness of the hard mask 16. Or, a two-stage CMP process may be utilized that a specific condition for polishing the ILD layer (for example oxide layer) is used in the first stage for a faster polishing, and another specific condition for polishing the ILD layer 28 and the hard mask 16 (for example silicon nitride layer) is used in the second stage, to remove a partial thickness of the hard mask 16, leaving a remaining hard mask 16a, as shown in FIG. 3.

For example, after the ILD layer 28 is polished in the first stage, it may be higher than the hard mask 16 and the CESL 26 (if formed) by about 50 to 150 angstroms, such as about 100 angstroms, as the ILD layer 28 shown in FIG. 2, but not limited thereto. As shown in FIG. 3, after the second stage of polishing, a partial thickness of the hard mask 16 has been removed, i.e. the remaining hard mask 16a has a thickness less than an original thickness of the hard mask 16. The original thickness of the hard mask 16 may be for example hundreds angstroms. In an embodiment, it may be for example 300 angstroms. The thickness of the portion of the hard mask being removed is not particularly limited. Since the hard mask is polished in the direction of from top to bottom, it can be also referred to as that the upper thickness of the hard mask is removed.” The upper surface of the obtained remaining hard mask 16a is often like a convex surface due to dishing effect. It is preferred that the remaining hard mask 16a still substantially entirely cover the dummy gate 18, such that it may ensure that the dummy gate 18 will not be damaged or attrite in the polishing and as a result that the height of the gate subsequently formed will not be affected. In view from the thickness controllability for the polishing, the remaining hard mask 16a preferably has a thickness for example from 50 to 150 angstroms. However, for the purpose desired in the present invention, it is not limited to such thickness range. If the remaining hard mask is thick, the following etch step may take relatively much time. If the remaining hard mask is too thin, a portion of the dummy gate might be damaged in the polishing; nevertheless, it is not restricted if such situation is acceptable. Accordingly, the thickness of the remaining hard mask is not particularly limited in the present invention.

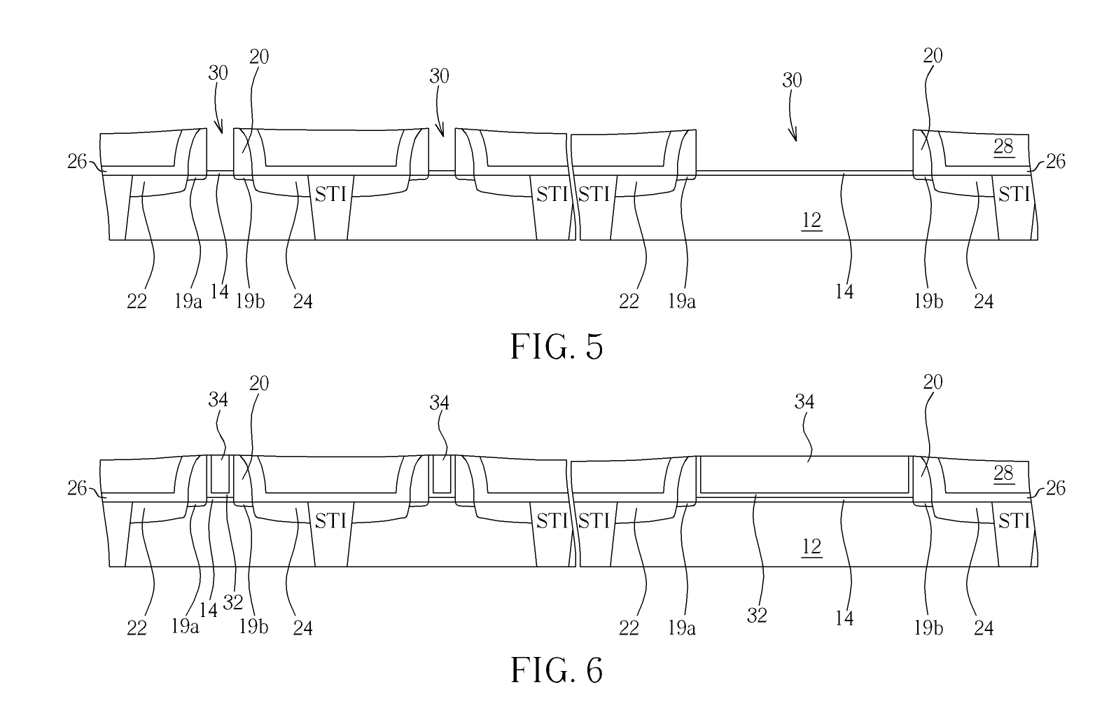

Thereafter, as shown in FIG. 4, the remaining hard mask 16a is removed through an etch process. The etch process may include a dry etch or a wet etch. When the hard mask include SiN material, a dry etch may be carried out using for example CF₄/N₂ as an etchant gas or a wet etch may be carried out using for example a hot phosphoric acid solution as an etchant. Thereafter, as shown in FIG. 5, the dummy gate 18 is removed to form a recess 30. This may be accomplished through for example an etch process which may include for example a dry etch or a wet etch. For example, in an embodiment, the dummy gate 18 (including for example polysilicon material) is dry-etched using chlorine gas (Cl₂) as an etchant, and thereafter a tetramethyl ammonium hydroxide (TMAH) solution is used as an etchant to remove the residual dummy gate 18. In the case that the remaining hard mask is removed by dry etch, the dry etch for the dummy gate may be carried out using the same chamber, just having the etchant gas changed.

Thereafter, as shown in FIG. 6, a gate material may be further filled in the recess 30 so as to form a gate. The gate material may include metal. For example, a work function metal layer 32 may be formed on the inter layer 14 and the sidewall of the recess 30, and a low-resistance metal layer 34 may be formed on the work function metal layer 32. The work function metal layer serves for regulating work function and may be a structure of single layer, multilayer, or composite layer, such as a conventional one. For used in a pMOS transistor, the work function metal may include for example titanium nitride (TiN), titanium carbide (TiC), tantalum nitride (TaN), tantalum carbide (TaC), tungsten carbide (WC), or aluminum titanium nitride (TiAlN). For used in an nMOS transistor, the work function metal may include for example titanium aluminide (TiAl), zirconium aluminide (ZrAl), tungsten aluminide (WAl), tantalum aluminide (TaAl), or hafnium aluminide (HfAl). The low-resistance metal layer may be a structure of single layer, multilayer, or composite layer, such as a conventional one employed in a metal gate and may include, for example, aluminum (Al), titanium (Ti), tantalum (Ta), tungsten (W), niobium (Nb), molybdenum (Mo), copper (Cu), titanium nitride (TiN), titanium carbide (TiC), tantalum nitride (TaN), Ti/W, or Ti/TiN. The inter layer 14 may be a high-K material layer. The high-K material may be, for example, selected from the group consisting of silicon nitride (SiN), silicon oxynitride (SiON) and metal oxide. And the metal oxide may include hafnium oxide (HfO), hafnium silicon oxide (HfSiO), hafnium silicon oxynitride (HfSiON), aluminum oxide (AlO), lanthanum oxide (La₂O₃), lanthanum aluminum oxide (LaAlO), tantalum oxide (TaO), zirconium oxide (ZrO), zirconium silicon oxide (ZrSiO), or hafnium zirconium oxide (HfZrO).

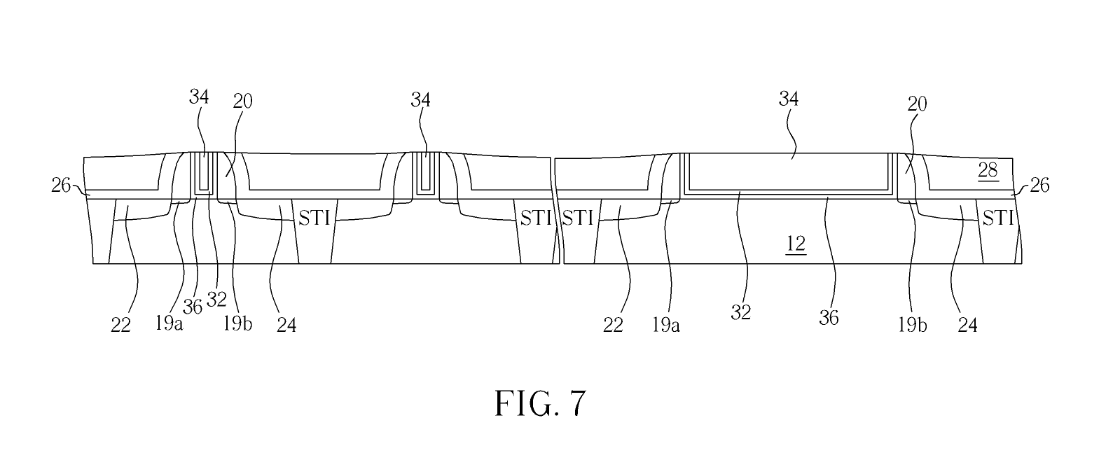

In another embodiment, the inter layer 14 may have function of protection or barrier, for protecting the semiconductor substrate 12 beneath the dummy gate 18 during removal of the dummy gate 18, as shown in FIG. 5. Accordingly, before the recess 30 is filled with gate material, the inter layer 14 may be or be not removed, and a gate dielectric layer may be further formed on the bottom of the recess 30 (or may further on the recess sidewall). The gate dielectric layer may include high-K material as mentioned above. Thereafter, a gate material is filled into the recess within which the high-K material layer is formed, to form a gate. In another embodiment, as shown in FIG. 7, with the inter layer 14 being removed or not removed, a high-K material layer 36 may be further formed on the bottom and the sidewall of the recess 30, a work function metal layer 32 is formed on the high-K material layer 36, and a low-resistance metal layer 34 is filled into the recess within which the high-K material layer 36 and the work function metal layer 32 are formed, to form a gate (or referred to as metal gate).

The method of the present invention can effectively solve the dummy gate rounding issue in fabrication of semiconductor structure having a large-sized metal gate, and this advantage is particularly significant with respect to fabrication of a plurality of gates with variously large and small sizes on wafer, to obtain MOS transistor structures having gates in substantially the same height.

According to the spirit of the present invention as described above, in another aspect of the present invention, a method of fabricating a semiconductor structure is provided. As shown in FIG. 2, a substrate (such as the semiconductor substrate 12) is provided. A material layer (such as a polysilicon layer) is formed on the substrate. A hard mask 16 is formed on the material layer, and the hard mask is patterned. The material layer is etched through the hard mask 16 to form a patterned material layer (such as the dummy gate 18). A dielectric layer (such as an ILD layer 28) is formed and covers the substrate, and the dielectric layer is higher than the hard mask 16. The dielectric layer is planarized, as shown in FIG. 3, to further remove a partial thickness of the hard mask 16, and the remaining hard mask 16a has a thickness less than an original thickness of the hard mask 16. The planarization of the dielectric layer may include a one- or two-stage chemical mechanical polishing process, as described above. As shown in FIG. 4, the remaining hard mask 16a is removed through an etch process (which may include a dry etch or a wet etch), as described above. As shown in FIG. 5, the patterned material layer is removed through, for example, a wet etch or a dry etch to form a recess 30.

Those skilled in the art will readily observe that numerous modifications and alterations of the device and method may be made while retaining the teachings of the invention.

1. A method of fabricating semiconductor structures, comprising:
providing a semiconductor substrate;
forming a plurality of dummy gate structures on the semiconductor substrate respectively comprising an inter layer, a dummy gate, and a hard mask in order from bottom to top;
forming an inter-layer dielectric layer on the semiconductor substrate, wherein the inter-layer dielectric layer is higher than the hard masks;
planarizing the inter-layer dielectric layer to further remove a partial thickness of the hard masks, wherein remaining hard masks have a thickness less than an original thickness of the hard masks;
removing the remaining hard masks through an etch process; and
removing the dummy gates.

2. The method of fabricating semiconductor structures according to claim 1, wherein after removing the dummy gates to form a plurality of recesses, further comprising filling a gate material into the recesses to form a plurality of gates.

3. The method of fabricating semiconductor structures according to claim 2, wherein the gate material comprises metal.

4. The method of fabricating a semiconductor structures according to claim 2, wherein the gate material comprises a work functional metal on the inter layer and a sidewall of each recess and a low-resistance metal on the work functional metal.

5. The method of fabricating semiconductor structures according to claim 1, wherein the inter layer comprises a high-dielectric constant material.

6. The method of fabricating semiconductor structures according to claim 1, further comprising forming a plurality of lightly-doped sources/drains in the semiconductor substrate at each of two sides of the dummy gates.

7. The method of fabricating semiconductor structures according to claim 1, further comprising:
forming a spacer on a sidewall of each dummy gate structure; and
forming a source/drain in the semiconductor substrate at each of two sides of the spacer.

8. The method of fabricating semiconductor structures according to claim 7, after forming the sources/drains and before forming the inter-layer dielectric layer, further comprising:
forming a contact etch stop layer on the semiconductor substrate, the spacers and the hard masks.

9. The method of fabricating semiconductor structures according to claim 1, wherein planarizing the inter-layer dielectric layer comprises carrying out a two-stage chemical mechanical polishing (CMP) process, wherein the two-stage CMP process comprises a first CMP process and a second CMP process subsequent to the first CMP process.

10. The method of fabricating semiconductor structures according to claim 1, wherein removing the remaining hard masks through the etch process comprises carrying out a dry etch.

11. The method of fabricating semiconductor structures according to claim 1, wherein removing the remaining hard masks through the etch process comprises carrying out a wet etch.

12. The method of fabricating semiconductor structures according to claim 1, wherein removing the dummy gates to form the recesses comprises carrying out a dry etch process.

13. The method of fabricating semiconductor structures according to claim 1, wherein removing the dummy gates to form the recesses comprises carrying out a wet etch process.

14. The method of fabricating semiconductor structures according to claim 1, further comprising:
forming a high-K material layer on a bottom and a sidewall of each recess, and
filling a gate material into each recess within which the high-K material layer is formed, to form a gate.

15. The method of fabricating semiconductor structures according to claim 1, further comprising:
forming a high-K material layer on a bottom and a sidewall of each recess,
forming a work function metal layer on the high-K material layer, and
filling a low-resistance metal into each recess within which the high-K material layer and the work function metal layer are formed, to form a gate.

16. A method of fabricating semiconductor structures, comprising:
providing a substrate;
forming a material layer on the substrate;
forming a plurality of hard masks on the material layer, wherein the hard masks are patterned;
etching the material layer through the hard masks to form a plurality of patterned material layers;
forming a dielectric layer on the substrate, wherein the dielectric layer is higher than the hard masks;
planarizing the dielectric layer to remove a partial thickness of the hard masks, wherein remaining hard masks have a thickness less than an original thickness of the hard masks;
removing the remaining hard masks through an etch process; and
removing the patterned material layers.

17. The method of fabricating semiconductor structures according to claim 16, wherein the step of planarizing the dielectric layer comprises a first CMP process and a second CMP process subsequent to the first CMP process.

18. The method of fabricating semiconductor structures according to claim 16, wherein removing the remaining hard masks through the etch process comprises a dry etch.

19. The method of fabricating semiconductor structures according to claim 16, wherein removing the remaining hard masks through the etch process comprises a wet etch.

20. The method of fabricating semiconductor structures according to claim 16, wherein removing the patterned material layers comprises carrying out a dry etch process.

21. The method of fabricating semiconductor structures according to claim 16, wherein removing the patterned material layers comprises carrying out a wet etch process.
